(19) United States
(12) Patent Application Publication
(10) Pub. No.: US 2025/0287580 A1
(43) Pub. Date: Sep. 11, 2025

(54) SEMICONDUCTOR DEVICE AND FABRICATION METHOD THEREOF

(71) Applicant: Yangtze Memory Technologies Co., Ltd., Wuhan (CN)

(72) Inventors: Quan ZHANG, Wuhan (CN); Yanwei SHI, Wuhan (CN); Yaqin LIU, Wuhan (CN); Liang CHEN, Wuhan (CN); Lu ZHOU, Wuhan (CN); Zhixian MENG, Wuhan (CN)

(21) Appl. No.: 18/886,971

(22) Filed: Sep. 16, 2024

(30) Foreign Application Priority Data
Mar. 5, 2024 (CN) 202410253724.0

(51) Int. Cl. H10B 12/00; H01L 21/266; H01L 21/308; H01L 21/768; H01L 29/423

(52) U.S. Cl. CPC H10B 12/50; H01L 21/266; H01L 21/308; H01L 21/76838; H10B 12/01; H10D 64/514

(57) ABSTRACT

Semiconductor devices and fabrication methods of the semiconductor devices are provided. In one aspect, a method includes: forming a gate layer on a substrate, forming a mask layer on the gate layer, etching the gate layer using the mask layer to form a gate, doping the substrate with ions to form source and drain regions on two sides of the gate, removing the mask layer, and forming gate sidewalls covering the two sides of the gate.

### CROSS-REFERENCE TO RELATED APPLICATIONS

This application claims the benefit of priority to Chinese Patent Application No. 202410253724.0, filed on Mar. 5, 2024, the disclosure of which is hereby incorporated by reference in its entirety.

### TECHNICAL FIELD

The present disclosure relates to the field of semiconductor fabrication, and in particular to a semiconductor device and a fabrication method thereof.

### BACKGROUND

With the development of semiconductor technology, the number of stacked layers in a three-dimensional (3D) memory is increased, the size of a memory array on chip is continuously decreased, and thus the size of the peripheral circuit (CMOS) matching the memory array in size also needs to be decreased. Furthermore, since the size of a page buffer (PB) make up a large proportion of the area of the peripheral circuit, it is especially important to reduce the size of the page buffer.

### SUMMARY

In view of this, the implementations of the present disclosure provide a semiconductor device and a fabrication method thereof.

In order to achieve the above-mentioned object, the technical solution of the present disclosure is implemented as follows.

In the first aspect, the implementations of the present disclosure provide a method of fabricating a semiconductor device. The method includes: forming a gate layer on a substrate; forming a first mask layer on the gate layer; etching the gate layer using the first mask layer to form a gate; doping the substrate with ions to form source/drain regions on both sides of the gate; removing the first mask layer; and forming gate sidewalls covering the sides of the gate.

In some implementations, the method further includes: forming a conductive contact layer on the source/drain regions and a gate conductive layer on the gate.

In some implementations, the method further includes: forming an interlayer dielectric layer covering the semiconductor device; etching the interlayer dielectric layer using a mask for a contact hole to form the contact hole extending through the interlayer dielectric layer to the conductive contact layer; and etching the interlayer dielectric layer using a mask for a first wiring layer to enlarge an opening of the contact hole at the top to form a wiring opening.

In some implementations, the method further includes: filling the contact hole to form a conductive structure in a portion of the contact hole other than the wiring opening and form the first wiring layer in the wiring opening.

In some implementations, the substrate includes a first region and a second region, and etching the gate layer using the first mask layer to form the gate includes: etching the gate layer using the first mask layer to form a first gate in the first region and a second gate in the second region, wherein a thickness of a gate oxide layer in the first region is larger than the thickness of the gate oxide layer in the second region.

In some implementations, after removing the first mask layer, the method further includes: doping the substrate in the second region with ions to form source/drain regions on both sides of the second gate.

In some implementations, the method further includes: forming a second wiring layer over and electrically connected to the first wiring layer that serves as a jumper between the conductive structure and the second wiring layer.

In some implementations, a thickness of the gate layer is in the range of 700 to 1200 angstroms.

In some implementations, a height of the conductive structure is in the range of 1500 to 4000 angstroms.

In some implementations, a width of the conductive structure at the bottom is in the range of 35 to 45 nm.

In some implementations, a width of the first wiring layer is in the range of 60 to 180 nm.

In some implementations, a thickness of each of the gate sidewalls in a first direction is in the range of 38 to 47 nm with the first direction being the direction from close to the gate to far away from the gate.

In the second aspect, the implementations of the present disclosure provide a semiconductor device, which includes: a substrate; and a transistor disposed on the substrate, wherein a gate of the transistor has a thickness in the range of 700 to 1200 angstroms.

In some implementations, the transistor further includes: a conductive contact layer disposed on source/drain regions of the transistor; and a gate conductive layer disposed on the gate.

In some implementations, the semiconductor device further includes: a conductive structure electrically connected to the conductive contact layer; and a first wiring layer electrically connected to the conductive structure.

In some implementations, the semiconductor device further includes: a second wiring layer electrically connected to the first wiring layer that serves as a jumper between the conductive structure and the second wiring layer.

In some implementations, a height of the conductive structure is in the range of 1500 to 4000 angstroms.

In some implementations, a width of the conductive structure at the bottom is in the range of 35 to 45 nm.

In some implementations, a width of the first wiring layer is in the range of 60 to 180 nm.

In some implementations, the transistor further includes gate sidewalls covering the sides of the gate, and the thickness of each of the gate sidewalls in a first direction is in the range of 38 to 47 nm with the first direction being the direction from close to the gate to far away from the gate.

In the third aspect, the implementations of the present disclosure provide a semiconductor device, which includes: a transistor; a conductive structure electrically connected to the transistor; a first wiring layer; and a second wiring layer, wherein the first wiring layer serves as a jumper between the conductive structure and the second wiring layer.

In some implementations, the semiconductor device further includes: first contacts between the first wiring layer and the second wiring layer with the first contacts and the first wiring layer as a whole serving as a jumper between the conductive structure and the second wiring layer.

In some implementations, the transistor comprises a high-voltage transistor, and the gate of the high-voltage transistor has a thickness in the range of 700 to 1200 angstroms.

In some implementations, a height of the conductive structure is in the range of 1500 to 4000 angstroms.

In some implementations, a width of the conductive structure at the bottom is in the range of 35 to 45 nm.

In some implementations, a width of the first wiring layer is in the range of 60 to 180 nm.

The implementations of the present disclosure provide a method of fabricating a semiconductor device and a semiconductor device. The method includes: forming a gate layer on a substrate; forming a first mask layer on the gate layer; etching the gate layer using the first mask layer to form a gate; doping the substrate with ions to form source/drain regions on both sides of the gate; removing the first mask layer; and forming gate sidewalls covering the sides of the gate. In the implementations of the present disclosure, the first mask layer may be removed after formation of the source/drain regions on both sides of the gate to use the first mask layer as the protection layer of the gate, so that the thickness of the gate may be reduced and thus the size of peripheral circuit may be reduced effectively.

### BRIEF DESCRIPTION OF DRAWINGS

FIG. 1 is a structural diagram of a memory device in an implementation provided by the present disclosure;

FIG. 2 is a flow chart illustrating operations of a method of fabricating a semiconductor device provided in an implementation of the present disclosure;

FIGS. 3a to 3j are cross-sectional diagrams illustrating a fabrication process of a semiconductor device provided in an implementation of the present disclosure;

FIG. 4 is a cross-sectional diagram of the conductive structure and the first wiring layer provided in an implementation of the present disclosure;

FIG. 5 is a top view of two semiconductor devices provided in an implementation of the present disclosure; and

FIG. 6 is a structural diagram of a semiconductor device provided in an implementation of the present disclosure.

### DETAILED DESCRIPTION

The technical solutions in implementations of the present disclosure will be described below clearly and completely in connection with implementations of the present disclosure and accompanying drawings. However, it is obvious that the described implementations are only some, not all, implementations of the present disclosure. All other implementations obtained by those skilled in the art based on implementations of the present disclosure without any creative works fall within the scope claimed by the present disclosure.

In the description hereafter, many details are provided to facilitate more thorough understanding of the present disclosure. However, it is apparent for those skilled in the art that the present disclosure can be implemented without one or more of these details. In other examples, in order not to obscure the present disclosure, some technical features well known in the art will not be described. That is to say, not all features of practical implementations will be described herein and well-known functions and structures will not be described in detail.

In accompanying drawings, dimensions and relative sizes of layers, regions and elements may be exaggerated for clearance. The same reference numerals refer to the same elements throughout the specification.

It should be appreciated that when an element or a layer is said to be “over”, “adjacent to”, “connected to” or “coupled to” another element or layer, it may be directly over, adjacent to, connected to or coupled to the another element or layer or an intervening element or layer may exist therebetween. On the contrary, when an element is said to be “directly on”, “directly adjacent to”, “directly connected to” or “directly coupled to” another element or layer, there is no intervening element or layer therebetween. It should be appreciated that although various elements, components, regions, layers and/or parts may be described using terms “first”, “second”, “third” or the like, they are not limited by those terms. The terms are only used to distinguish one element, component, region, layer or part from another element, component, region, layer or part. Therefore, a first element, component, region, layer or part discussed hereafter may be instead expressed as a second element, component, region, layer or part without departing from the teaching of the present disclosure. When a second element, component, region, layer or part is in discussion, it is not intended to indicate that a first element, component, region, layer or part must exist.

Spatially relative terms, such as “below”, “beneath”, “lower”, “under”, “over” and “above”, are used herein for ease of description to explain the relationship of one element or feature with other element(s) or feature(s) as shown in the figures. It should be appreciated that, in addition to the orientations shown in the figures, different orientations of devices in use and operation are also intended to be covered by those spatially relative terms. For example, if a device is turned upside down, the element or feature described to be “beneath”, “under” or “below” another element or feature will have the orientation of being “over” the another element or feature. Therefore, example terms “beneath” and “under” may include orientations of both “below” and “above”. Device may be otherwise oriented (rotated 90 degrees or at other orientations) and the spatially relative descriptors used herein may likewise be interpreted accordingly.

Terminology is used herein only for description of implementations and in no way for limiting the present disclosure. As used herein, the terms “a”, “an” and “the” in singular forms are also intended to cover plural forms, unless the context clearly indicates otherwise. It should be also appreciated that terms “comprise”, “comprising”, “include” and/or “including”, as used in the specification, specify presence of the mentioned features, integers, steps, operations, elements and/or components, but do not exclude presence or addition of one or more other features, integers, steps, operations, elements, components and/or combinations thereof. As used herein, the term “and/or” includes any and all combinations of relevant listed items.

For through understanding of the present disclosure, detailed steps and structures will be provided in the following description to set fourth technical solutions of the present disclosure. Detailed description of the implementations of the present disclosure is as follows, however the present disclosure may have other implementations in addition to the detailed description.

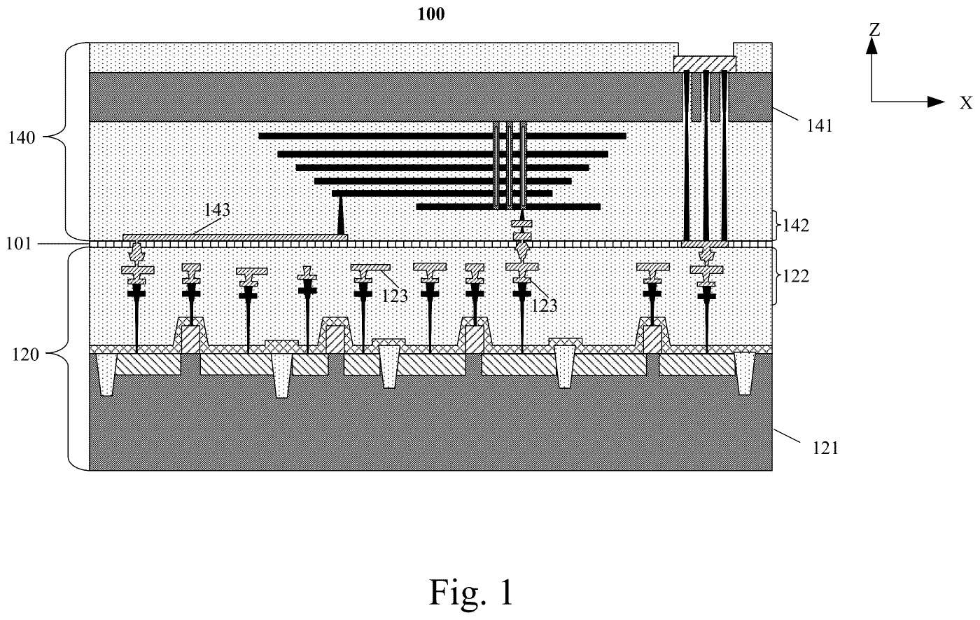

FIG. 1 is a structural diagram of a memory device provided in an implementation of the present disclosure. With reference to FIG. 1, the memory device 100 includes a first semiconductor structure 120 and a second semiconductor structure 140, wherein a bonding surface 101 are included between the first semiconductor structure 120 and the second semiconductor structure 140 and an external pad (not shown in the figure) may be formed at the bonding surface for connecting the first semiconductor structure 120 and the second semiconductor structure 140.

The first semiconductor structure 120 includes a CMOS substrate 121 suitable for peripheral circuit (CMOS) and a plurality of CMOS transistors (including a high-voltage transistor and a low-voltage transistor) are formed on the CMOS substrate 121. A PMOS transistor and a NMOS transistor are collectively referred to as the CMOS transistor. A CMOS interconnection structure 122 is formed over the CMOS transistors and includes pads, vertical interconnect accesses (VIAs) and a CMOS wiring layer 123. The CMOS interconnection structure 122 is electrically connected to the gates, sources and drains of the CMOS transistors through a conductive structure (contact). The CMOS interconnection structure 122 may further include one or more dielectric layers, in which the CMOS wiring layer and VIAs may be formed.

The second semiconductor structure 140 includes an array substrate 141, on which a memory cell array is formed. An array interconnection structure 142 is formed over the memory cell array and includes an array wiring layer 143. The array wiring layer 143 is electrically connected with the CMOS wiring layer 123, implementing electrical connection between the first semiconductor structure 120 and the second semiconductor structure 140.

With reference to FIG. 1, since the CMOS wiring layer 123 extends laterally in a first direction and a second direction and has a relatively large size, causing relatively great difficulty of the routing for connection between the semiconductor structures. Since there are a high-voltage transistor 124 and a low-voltage transistor 125 in the first semiconductor structure, meanwhile it is difficult for the height of the gate of the high-voltage transistor 124 and the height of the interlayer dielectric layer to be lowered, and the memory cell array is closely related to the size of the peripheral circuit, it is especially important to reduce the difficulty of connection between the semiconductor devices while reducing the size of the peripheral circuit.

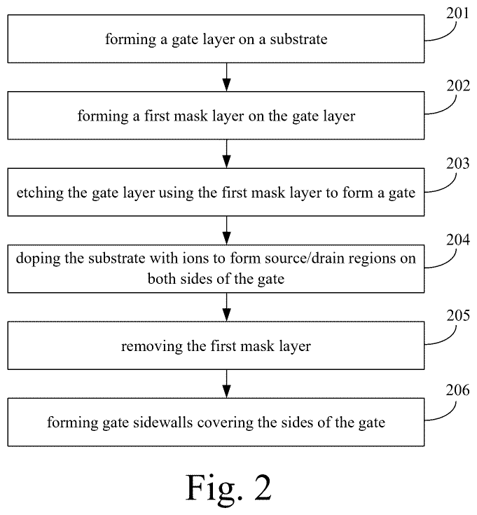

In view of this, the implementations of the present disclosure provide a method of fabricating a semiconductor device. FIG. 2 is a flow chart illustrating operations of a method of fabricating a semiconductor device provided in an implementation of the present disclosure. With reference to FIG. 2, the fabrication method includes the following operations.

In operation 201, a gate layer is formed on a substrate.

In operation 202, a first mask layer is formed on the gate layer.

In operation 203, the gate layer is etched using the first mask layer to form a gate.

In operation 204, the substrate is doped with ions to form source/drain regions on both sides of the gate.

In operation 205, the first mask layer is removed.

In operation 206, gate sidewalls covering the sides of the gate are formed.

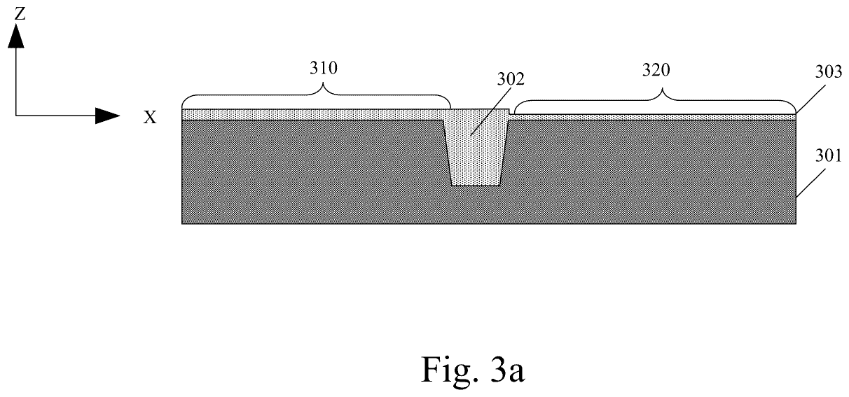

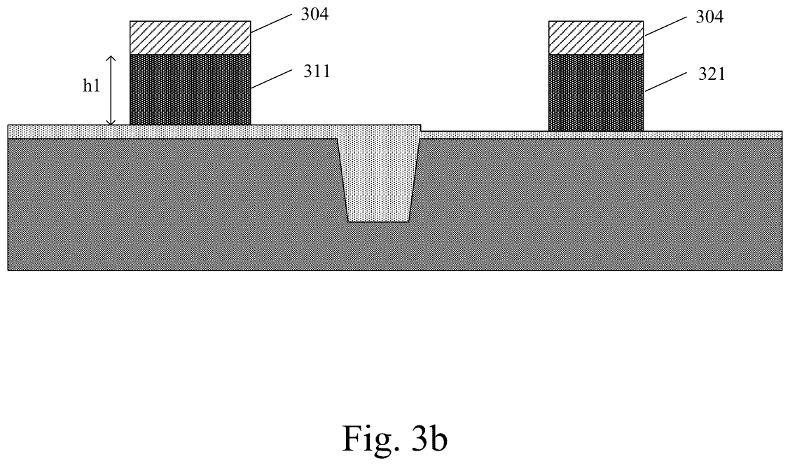

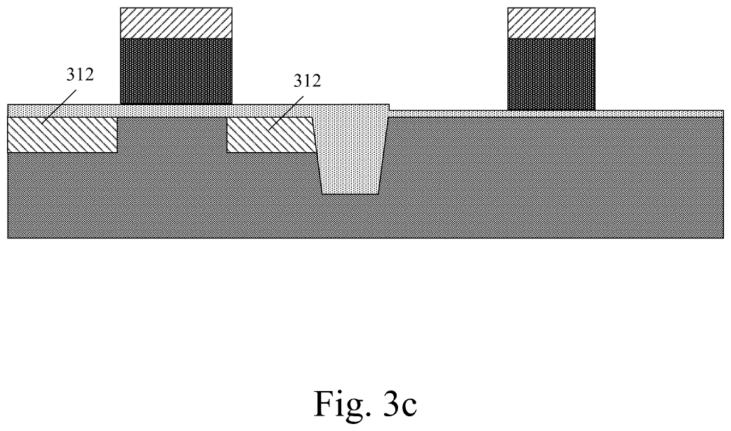

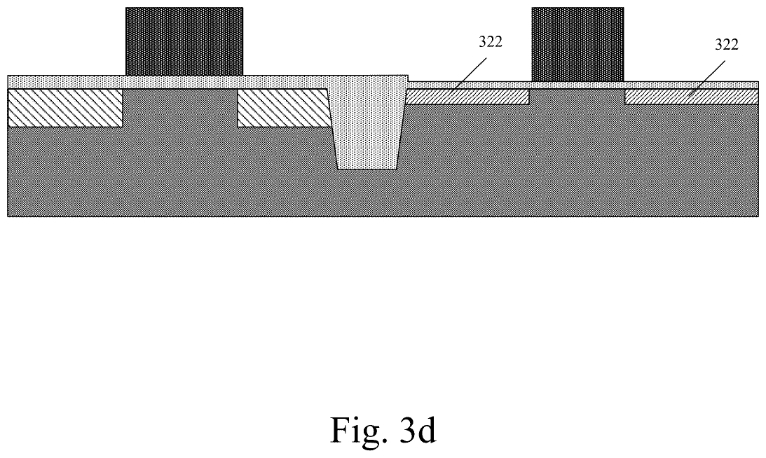

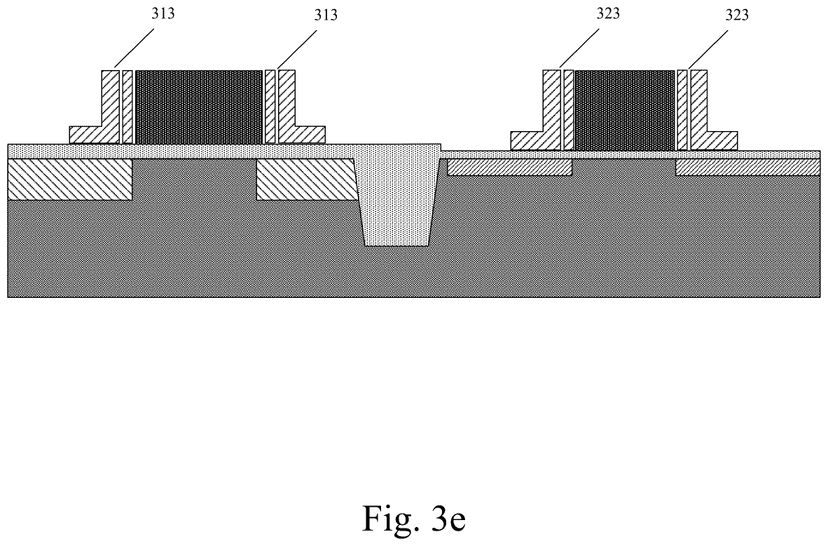

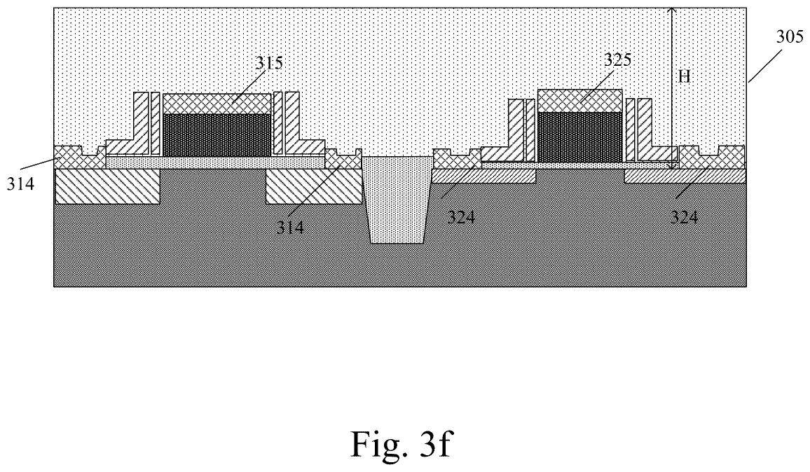

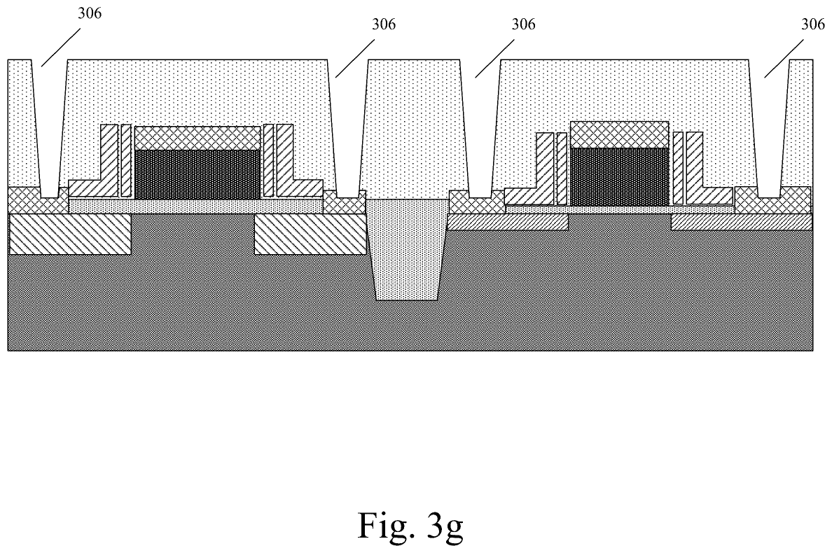

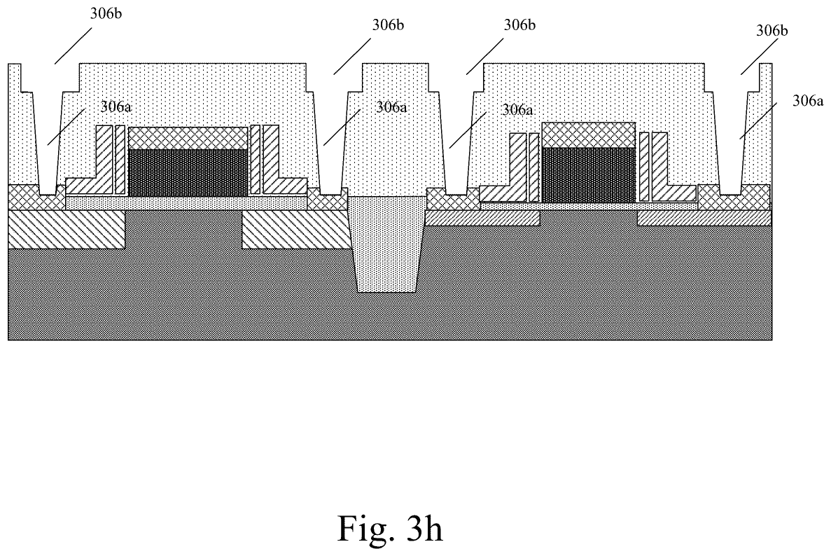

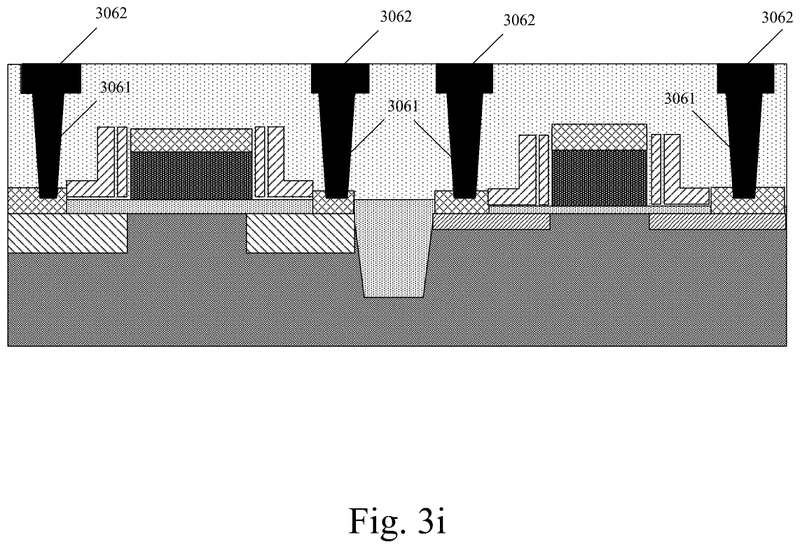

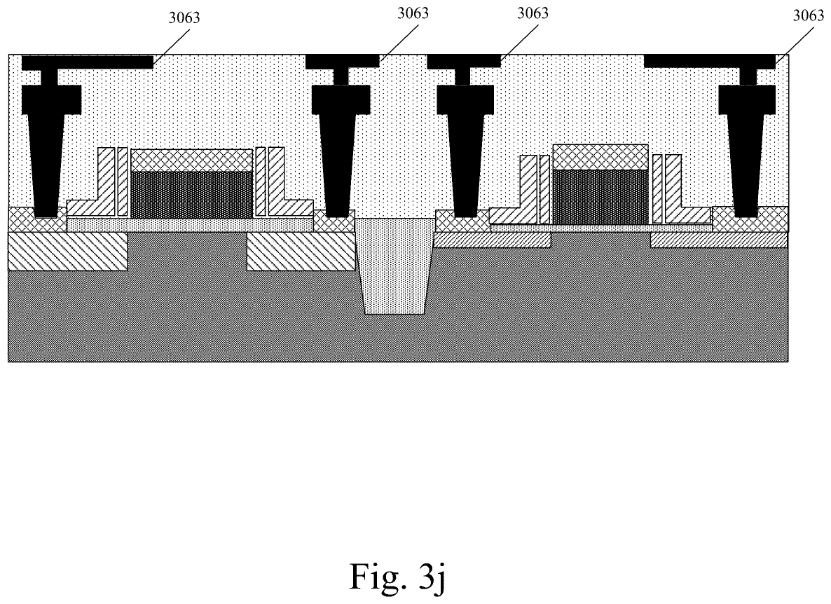

FIGS. 3a to 3j are cross-sectional diagrams illustrating a fabrication process of a semiconductor device provided in an implementation of the present disclosure. It is to be noted that FIGS. 3a to 3j are diagrams of an implementation process completely reflecting a method of fabricating a semiconductor device and the parts not labeled in some of the figures can be used in common. Hereafter, the method of fabricating a semiconductor device in the implementation of the present disclosure will be described in detail in combination with FIG. 2 and FIGS. 3a to 3j.

It is to be noted that, for easy description, in the implementations of the present disclosure, the first direction and the second direction represent two orthogonal directions in the substrate plane, i.e. two lateral directions extending laterally in the substrate plane; the third direction is the direction perpendicular to the substrate plane. Illustratively, the first direction is the X direction in the figure, the second direction is the Y direction in the figure and the third direction is the Z direction in the figure.

With reference to FIG. 3a, the implementations of the present disclosure provide a substrate 301 having a material that may include a silicon (Si) substrate, a germanium (Ge) substrate, a silicon germanium (SiGe) substrate, a silicon-on-insulator (SOI) substrate or a germanium-on-insulator (GOI) substrate, and the like. A shallow trench isolation structure 302 has been formed in the substrate 301 and is configured to define an active region or isolate transistors from each other. The substrate 301 may include a first region 310 and a second region 320, and the shallow trench isolation structure 302 may electrically isolate a transistor in the first region 310 from a transistor in the second region 320. Here, the first region 310 is configured to form a high-voltage (HV) transistor and the second region 320 is configured to form at least one of a low-voltage (LV) transistor or a low-low-voltage (LLV) transistor.

The operation of forming the shallow trench isolation structure 302 includes: forming a mask layer for shallow trench on the substrate 301 and etching the substrate 301 using the mask layer for shallow trench to form a shallow trench, wherein the material of the mask layer for shallow trench may include one or more of silicon oxide, silicon nitride, silicon oxynitride and silicon carbide and the shallow trench may be formed using a plasma dry etch process, a gas reaction dry etch process or a wet etch process. Further, an isolation material is deposited in the shallow trench to form the shallow trench isolation structure 302. The shallow trench isolation structure 302 may be formed by the process such as a physical vapor deposition (PVD) process, a chemical vapor deposition (CVD) process or an atomic layer deposition (ALD) process and then the mask layer for shallow trench is removed by dry or wet etching.

In some implementations, the substrate includes a first region and a second region. Etching the gate layer using the first mask layer to form the gate includes: etching the gate layer using the first mask layer to form a first gate in the first region and a second gate in the second region, wherein the thickness of the gate oxide layer in the first region is larger than the thickness of the gate oxide layer in the second region.

In some implementations, with continued reference to FIG. 3a, a gate oxide layer 303 is formed on the substrate 301 for isolating the gate of transistor from the channel, and may be a silicon oxide layer formed using a thermal oxidation method or an in-situ steam generation method. In a process of forming the gate oxide layer 303, a mask may be utilized properly to make the thickness of the gate oxide layer 303 in the first region 310 larger than the thickness of the gate oxide layer 303 in the second region. The thickness of the gate oxide layer 303 in the first region 310 is larger than the thickness of the gate oxide layer 303 in the second region 320. A larger thickness of gate oxide layer makes the transistor formed in the first region 310 have higher capability of enduring voltages, and a smaller thickness of gate oxide layer enables ions to still penetrate the gate oxide layer to form sources/drains for the second region 320 when the energy for ion implantation is low.

In some implementations, the thickness of the gate layer is in the range of 700 to 1200 angstroms.

In some implementations, with reference to FIG. 3b, a gate layer is formed on the gate oxide layer 303 and a first mask layer 304 is formed on the gate layer. The gate layer is etched using the first mask layer 304 to form a first gate 311 in the first region 310 and a second gate 321 in the second region 320. The material of gate layer includes polysilicon, doped polysilicon or the like. In some implementations, the thickness h1 of the gate layer (the first gate 311) in the first region is in the range of 700 to 1200 angstroms. In an example, the thickness h1 of the gate layer (the first gate 311) in the first region may be 850 angstroms.

In some implementations, with reference to FIG. 3c, the substrate 301 in the first region 310 is doped with ions to form first source/drain regions 312 on both sides of the first gate 311. Here, the first mask layer 304 may serve as a protective layer for the first gate 311 and the second gate 321 to protect them during the subsequent ion doping operation, so that the ions may be prevented from breaking through the first gate 311 while avoiding the ion implantation into the channel and thus the thickness of the first gate 311 may be reduced without affecting device performance under protection of the first mask layer 304.

In some implementations, after removing the first mask layer, the method further includes: doping the substrate in the second region with ions to form source/drain regions on both sides of the second gate.

With reference to FIG. 3d, after the first source/drain regions 312 are formed on both sides of the first gate 311, the first mask layer 304 may be removed by dry or wet etching to enlarge the process window for ion doping of the substrate in the second region 320. Further, an LDD process is performed on the substrate 301 in the second region 320 to form second source/drain regions 322 on both sides of the second gate 321.

In some implementations, the thickness of each of the gate sidewalls in a first direction is in the range of 38 to 47 nm with the first direction being the direction from close to the gate to far away from the gate.

Further, with reference to FIG. 3e, forming the gate sidewalls covering the sides of the gate includes: forming a first gate sidewall 313 covering the sides of the first gate 311 and a second gate sidewall 323 covering the sides of the second gate 321 by a sidewall process. The first gate sidewall 313 and the second gate sidewall 323 may each be a single-layered structure or a multiple-layered structure as shown in the figures. The first gate sidewall 313 and the second gate sidewall 323 have a thickness in the first direction in the range of 38 to 47 nm. In an example, the thickness of the first gate sidewall 313 and the second gate sidewall 323 in the first direction may be 43 nm.

In some implementations, the first source/drain regions 312 and the second source/drain regions 322 may serve as the source and the drain for the first gate 311 and the source and the drain for the second gate 321, respectively.

In some other implementations, the first source/drain regions 312 may be lightly doped source/drain regions and may be implanted with ions using the first gate sidewall 313 to form heavily doped source/drain regions (not shown in figure). The heavily doped source/drain regions in the first source/drain regions 312 as well as the second source/drain regions 322 may serve as the source and the drain of the first gate 311 and the source and the drain of the second gate 321 respectively. Here, the heavily doped source/drain regions in the first source/drain regions 312 facilitate reduction of potential barrier in metal leading out to achieve ohmic contact. It is to be noted that the first mask layer 304 may be removed after forming the heavily doped source/drain regions in the first source/drain regions 312 to prevent ions from breaking through the first gate 311 during formation of the heavily doped source/drain regions in the first source/drain regions 312.

In some implementations, the method further includes: forming a conductive contact layer on the source/drain regions and a gate conductive layer on the gate.

In some implementations, with reference to FIG. 3f, a first conductive contact layer 314 and a second conductive contact layer 324 are formed on the first source/drain region 312 and the second source/drain region 322 respectively while a first gate conductive layer 315 and a second gate conductive layer 325 are formed on the first gate 311 and the second gate 321 respectively. Here, the conductive contact layer and the gate conductive layer may be formed by depositing a conductive material or by metallization and may include metal silicide.

In some implementations, the method further includes: forming an interlayer dielectric layer (ILD) covering the semiconductor device; etching the interlayer dielectric layer using a mask for a contact hole to form the contact hole extending through the interlayer dielectric layer to the conductive contact layer; and etching the interlayer dielectric layer using a mask for a first wiring layer to enlarge opening of the contact hole at the top to form a wiring opening.

In some implementations, with continued reference to FIG. 3f, an interlayer dielectric layer 305 covering the substrate 301 is formed, wherein the thickness H of the interlayer dielectric layer 305 may be 2000 angstroms. With reference to FIG. 3g, a mask layer for contact hole having a first opening and a second opening (not shown in the figure) is formed on the interlayer dielectric layer 305, the projections of the first opening and the second opening on the substrate 301 overlap at least partially the first conductive contact layer 314 and the second conductive contact layer 324 respectively, the interlayer dielectric layer 305 is etched using the mask layer for contact hole with the conductive contact layers 314 and 324 serving as an etch stop layer, so as to form the contact hole 306 extending through the interlayer dielectric layer 305 to the first conductive contact layer 314 and the second conductive contact layer 324. It is to be noted that the interlayer dielectric layer 305 may be formed of a dielectric material including, but not limited to, silicon oxide, silicon nitride, silicon oxynitride, a low-k dielectric or any combination thereof.

Further, with reference to FIG. 3h, the mask layer for contact hole is removed, a mask layer for a first wring layer having a third opening and a fourth opening (not shown in the figure) is formed on the interlayer dielectric layer 305, the projections of the third opening and the fourth opening on the substrate 301 respectively overlap the first opening and the second opening and are larger than them in size, and the interlayer dielectric layer 305 is etched using the mask layer for the first wiring layer to enlarge the opening of the contact hole at the top to form a wiring opening 306b. The contact hole having its openings enlarged at the top include the wiring opening 306b and the portion 306a other than the wiring opening. Here, the wiring opening 306b is configured to form a first wiring layer (Metal1) and the portion 306a other than the wiring opening is configured to form a conductive structure (contact).

In some implementations, the method further includes: filling the contact hole to form the conductive structure in the portion of the contact hole other than the wiring opening and form the first wiring layer in the wiring opening.

As such, it can be realized to form the conductive structure and the first wiring layer at the same time through only one filling operation. Since it is not necessary to form the conductive structure and the first wiring layer separately, the process operations and costs can be reduced efficiently.

It is to be noted that since the wiring opening is based on the formation of contact hole and formed by enlarging the contact hole at the top, during formation of the interlayer dielectric layer, the deposition thickness of the interlayer dielectric layer needs to be determined according to the size of the conductive structure and the first wiring layer to be formed in the third direction.

In some implementations, the height of the conductive structure is in the range of 1500 to 4000 angstroms. The height of the conductive structure is the length of the conductive structure in the third direction.

In some implementations, with reference to FIG. 3i, a conductive material is filled into the contact hole 306 to form the conductive structure 3061 in the portion 306a of the contact hole 306 other than the wiring opening and the first wiring layer 3062 in the wiring opening 306b. In some implementations, the height h2 of the conductive structure 3061 is in the range of 1500 to 4000 angstroms. In an example, the height h2 of the conductive structure 3061 may be 2000 angstroms.

In some implementations, the width of the conductive structure at the bottom is in the range of 35 to 45 nm.

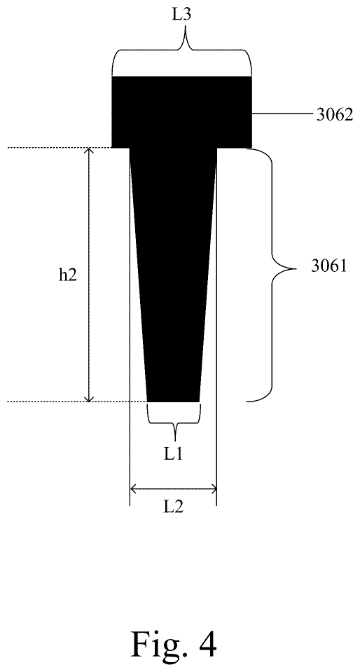

FIG. 4 is a cross-sectional diagram of the conductive structure and the first wiring layer provided in an implementation of the present disclosure. With reference to FIG. 4, the width L1 of the conductive structure 3061 at the bottom is in the range of 35 to 45 nm, while in some other implementations, the sizes of the conductive structures (the widths at their bottom) are mostly larger than 50 nm. In some implementations, as shown in FIG. 4, the width L2 of the conductive structure 3061 at the top is in the range of 50 to 60 nm, and the width L3 of the first wiring layer 3062 is in the range of 60 to 180 nm. In an example, the width L3 of the first wiring layer 3062 may be 120 nm. Since the thickness of the interlayer dielectric layer is relatively small, the size of the conductive structure 3061 formed by the method of fabricating a semiconductor device in an implementation of the present disclosure may be significantly reduced, so that flexibility of wire-running in subsequent fabrication processes can be improved. Furthermore, the first wiring layer 3062 is significantly reduced in size and can be formed at the same operation as the conductive structure 3061, reducing the process operations and costs.

In some implementations, the method further includes: forming a second wiring layer (Metal 2) located over and electrically connected to the first wiring layer that serves as a jumper between the conductive structure and the second wiring layer.

In some implementations, with reference to FIG. 3j, a second wiring layer 3063 may be formed over the first wiring layer 3062 by depositing a second dielectric layer on the interlayer dielectric layer 305, etching the second dielectric layer using a photolithographic mask to form second wiring openings and filling a conductive material in the second wiring openings to form the second wiring layer 3063. The first wiring layer 3062 serves as a jumper between the conductive structure 3061 and the second wiring layer 3063 and the electrical connection between the transistor and the memory array may be achieved by routing from the second wiring layer 3063. In the implementation of the present disclosure, by the first wiring layer 3062 serving as a jumper and starting routing from the second wiring layer 3063, the height of the conductive structure may be reduced, while the performance of the high-voltage transistor is prevented from being affected by the routing. The second wiring layer 3063 includes a first routing extending in a first direction and a second routing extending in a second direction, and the first routing and the second routing can enable the electrical connection between the peripheral circuit and the memory array. It is to be noted that the material of the second interlayer dielectric layer may be the same as that of the interlayer dielectric layer 305.

With continued reference to FIG. 3i, a transistor formed in the first region 310 may jump to the second wiring layer 3063 through the first wiring layer 3062, and may be routed through the second wiring layer 3063 to enable the electrical connection between the transistor and the memory array, so that the distance between the routing and the transistor in the first region 310 is increased, enabling the transistor in the first region 310 to have improved capability of enduring voltage.

In some other implementations, the transistor formed in the second region 320 may be routed through the first wiring layer 3062 or the second wiring layer 3063 to enable the electrical connection between the transistor and the memory array, improving the flexibility of back-end-of-line (BEOL) interconnection for the transistor in the second region 320.

In some implementations, the width of the first wiring layer is in the range of 60 to 180 nm.

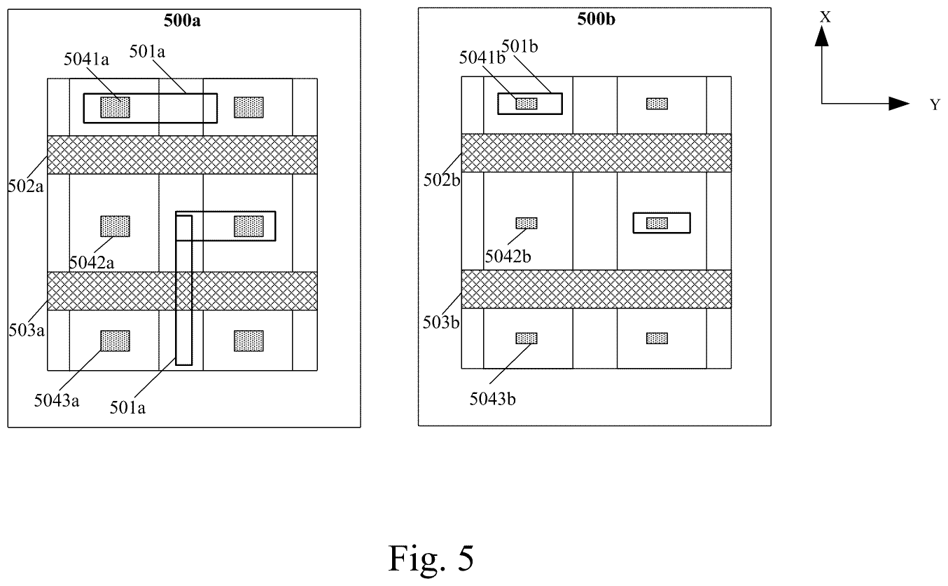

FIG. 5 is a top view of two semiconductor devices provided in an implementation of the present disclosure. With reference to FIG. 5, in some implementations, a semiconductor device 500a includes a wiring layer 501a, a first gate 502a in a first region (HV), a second gate 503a in a second region (LV/LLV) and conductive structures 5041a to 5043a on both sides of each of the first gate 502a and the second gate 503a with the conductive structure 5042a serving as a common conductive structure, wherein the wiring layer 501a extends laterally in a plane defined by a first direction and a second direction. In other words, the wiring layer 501a includes the routing extending in the first direction and the routing extending in the second direction. The projection of the wiring layer 501a on the plane defined by the first direction and the second direction is far bigger in size than the projection of the conductive structure on the plane. It is to be noted that the wiring layer 501a is Metall. In some other implementations, the semiconductor device 500b includes a first wiring layer 501b, a first gate 502b in a first region (HV), a second gate 503b in a second region (LV/LLV) and the conductive structures 5041b to 5043b on both sides of each of the first gate 502b and the second gate 503b with the conductive structure 5042b serving as a common conductive structure. Compared to the semiconductor device 500a, in the semiconductor device 500b, the first wiring layer 501b needs not to serve as the routing but only needs to serve as a jumper between the conductive structure 3061 and the second wiring layer 3063, so that the size of the first wiring layer 501b may be greatly reduced.

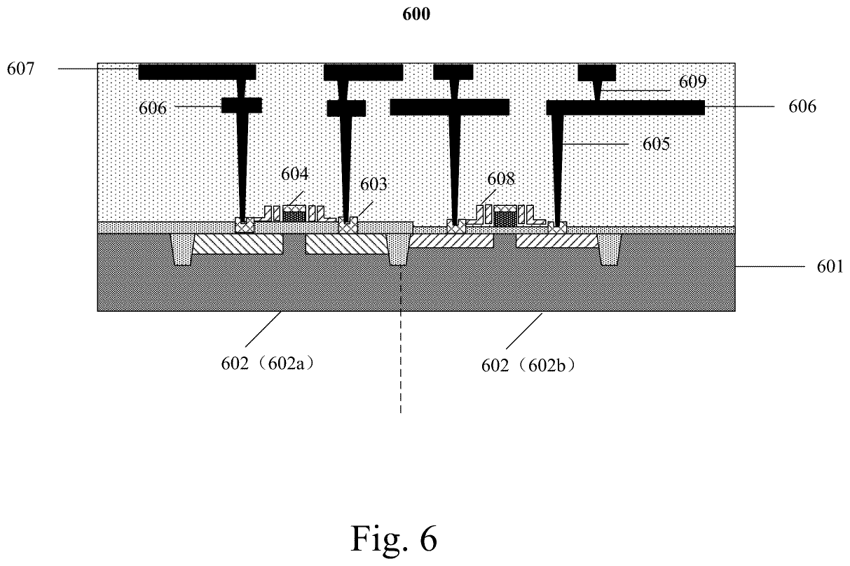

FIG. 6 is a structural diagram of a semiconductor device provided in an implementation of the present disclosure. The semiconductor device 600 includes: a substrate 601; and a transistor 602 disposed on the substrate, wherein the gate of the transistor 602 has a thickness in the range of 700 to 1200 angstroms.

In some implementations, the transistor 602 includes a high-voltage transistor 602a and a low-voltage/low-low-voltage transistor 602b and the thickness of the gate of the high-voltage transistor 602a may be 850 angstroms.

In some implementations, the transistor further includes: a conductive contact layer 603 disposed on the source/drain regions of the transistor 602; and a gate conductive layer 604 disposed on the gate of the transistor 602.

In some implementations, the semiconductor device further includes: a conductive structure 605 electrically connected to the conductive contact layer 603; and a first wiring layer 606 electrically connected to the conductive structure 605.

In some implementations, the semiconductor device further includes: a second wiring layer 607 electrically connected to the first wiring layer 606 that serves a jumper between the conductive structure 605 and the second wiring layer 607.

In some implementations, the first wiring layer 606 serves as a jumper between the conductive structure 605 and the second wiring layer 607, and the routing starts from the second wiring layer 607 to achieve the electrical connection between the transistor and the memory array. In the implementation of the present disclosure, by the first wiring layer 606 serving as a jumper and starting routing from the second wiring layer 607, the height of the conductive structure 605 may be reduced, while the performance of the high-voltage transistor in the transistors 602 is prevented from being affected by the routing. The second wiring layer 607 includes a first routing extending in a first direction and a second routing extending in a second direction, and the first routing and the second routing can enable the electrical connection between the peripheral circuit and the memory array.

In some implementations, the height of the conductive structure 605 is in the range of 1500 to 4000 angstroms.

In some implementations, the height of the conductive structure 605 may be 2000 angstroms and is the length of the conductive structure 605 in the third direction.

In some implementations, the width of the conductive structure 605 at the bottom is in the range of 35 to 45 nm.

In some implementations, the width of the first wiring layer 606 is in the range of 60 to 180 nm.

In some implementations, the width of the first wiring layer 606 is 120 nm.

In some implementations, since the first wiring layer 606 needs not to serve as the routing but only needs to serve as the jumper between the conductive structure 605 and the second wiring layer 607, the height of the conductive structure 605 will not be affected by the distance between the high-voltage transistor in the transistor 602 and the first wiring layer 606 while the size of the conductive structure 605 may be significantly reduced, improving the flexibility of the routing in subsequent fabrication processes and facilitating reduction of the size of peripheral circuit.

In some implementations, the transistor 602 further includes gate sidewalls 608 covering the sides of the gate. The thickness of each of the gate sidewalls 608 in a first direction is in the range of 38 to 47 nm with the first direction being the direction from close to the gate to far away from the gate.

In some implementations, the thickness of each of the gate sidewalls 608 in the first direction is 43 nm.

The implementations of the present disclosure further provide a semiconductor device 600, with reference to FIG. 6, the semiconductor device including: a transistor 602; a conductive structure 605 electrically connected to the transistor 602; a first wiring layer 606; and a second wiring layer 607, wherein the first wiring layer 606 serves as a jumper between the conductive structure 605 and the second wiring layer 607.

In some implementations, the first wiring layer 606 is configured to serve as a jumper between the conductive structure 605 and the second wiring layer 607, and a routing starts from the second wiring layer 607 to achieve the electrical connection between the transistors and the memory array. In the implementation of the present disclosure, by the first wiring layer 606 serving as a jumper and starting routing from the second wiring layer 607, the height of the conductive structure 605 may be reduced, while the performance of the high-voltage transistor in the transistors 602 is prevented from being affected by the routing. The second wiring layer 607 includes a first routing extending in a first direction and a second routing extending in a second direction, and the first routing and the second routing can enable the electrical connection between the peripheral circuit and the memory array.

In some implementations, the semiconductor device further includes: first contacts 609 between the first wiring layer 606 and the second wiring layer 607 with the first contacts 609 and the first wiring layer 606 as a whole serving as a jumper between the conductive structure 605 and the second wiring layer 607.

In some implementations, the transistor 602 includes a high-voltage transistor 602a, wherein the thickness of the gate of the high-voltage transistor 602a is in the range of 700 to 1200 angstroms.

In some implementations, the transistor 602 further includes an LV/LLV transistor 602b, wherein the high-voltage transistor 602a may achieve BEOL interconnection through the second wiring layer 607 and the LV/LLV transistor 602b may achieve BEOL interconnection through the first wiring layer 606 or the second wiring layer 607.

In some implementations, the height of the conductive structure 605 is in the range of 1500 to 4000 angstroms.

In some implementations, the height of the conductive structure 605 may be 2000 angstroms, and is the length of the conductive structure 605 in the third direction.

In some implementations, the width of the first wiring layer 606 is in the range of 60 to 180 nm.

In some implementations, the width of the conductive structure 605 at the bottom is in the range of 35 to 45 nm.

In some implementations, the width of the first wiring layer 606 is in the range of 60 to 180 nm.

In some implementations, the width of the first wiring layer 606 is 120 nm.

In some implementations, since the first wiring layer 606 needs not to serve as the routing but only needs to serve as a jumper between the conductive structure 605 and the second wiring layer 607, the height of the conductive structure 605 will not be affected by the distance between the high-voltage transistor 602a and the first wiring layer 606 while the size of the conductive structure 605 may be significantly reduced, improving the flexibility of the routing in subsequent fabrication processes and facilitating reduction of the size of the peripheral circuit.

It is to be noted here that the above description of the semiconductor device is similar to the description of the implementations of the method of fabricating a semiconductor device and the semiconductor device has beneficial effects similar to those of the fabrication method. Technical details not disclosed in implementations of the semiconductor device in the present disclosure can be understood by referring to the description of implementations of the method of fabricating a semiconductor device in the present disclosure.

The implementations of the present disclosure provide a method of fabricating a semiconductor device and a semiconductor device. The method includes: forming a gate layer on a substrate; forming a first mask layer on the gate layer; etching the gate layer using the first mask layer to form a gate; doping the substrate with ions to form source/drain regions on both sides of the gate; removing the first mask layer; and forming the gate sidewalls covering the sides of the gate. In the implementations of the present disclosure, the first mask layer may be removed after formation of the source/drain regions on both sides of the gate to use the first mask layer as the protection layer of the gate, so that the thickness of the gate may be reduced and the size of the peripheral circuit may be reduced effectively.

It should be understood that “one implementation” or “an implementation” mentioned throughout the specification means that particular features, structures or characteristics in association with the implementation may be included in at least one implementation of the present disclosure. Therefore, “in one implementation” or “in an implementation” mentioned throughout the specification refers not necessarily to the same implementation. Moreover, these particular features, structures or characteristics may be incorporated in one or more implementations in any suitable manner. It should be understood that, in various implementations of the present disclosure, the ordinal numbers of the various processes above are not intended to indicate that the processes must be performed in any sequential order, and the various processes should be performed in a sequential order determined depending on their functions and inherent logic. The implementation processes of implementations of the present disclosure should be not limited in this respect. The ordinal numbers in the above-mentioned implementations of the present disclosure are only for the purpose of description and imply no preference for any one or more implementations over the others.

Only implementations of the present disclosure are described above. It is not intended to limit the scope claimed by the present disclosure. All the equivalent structural transformations obtained using the contents of the specification and accompanying drawings in the present disclosure following the inventive concept of the present disclosure or direct/indirect application of the inventive concept in other related technical fields fall within the scope claimed by the present disclosure.

What is claimed is:

1. A method of fabricating a semiconductor device, comprising:
forming a gate layer on a substrate;
forming a mask layer on the gate layer;
etching the gate layer using the mask layer to form a gate;
doping the substrate with ions to form source and drain regions on two sides of the gate;
removing the mask layer; and
forming gate sidewalls covering the two sides of the gate.

2. The method of claim 1, further comprising:
forming a conductive contact layer on the source and drain regions and a gate conductive layer on the gate.

3. The method of claim 2, further comprising:
forming an interlayer dielectric layer covering the semiconductor device;
etching the interlayer dielectric layer using a mask for a contact hole to form the contact hole extending through the interlayer dielectric layer to the conductive contact layer; and
etching the interlayer dielectric layer using a mask for a first wiring layer to enlarge an opening of the contact hole to form a wiring opening.

4. The method of claim 3, further comprising:
filling the contact hole to form a conductive structure in a portion of the contact hole other than the wiring opening and form the first wiring layer in the wiring opening.

5. The method of claim 4, further comprising:
forming a second wiring layer over and electrically connected to the first wiring layer, wherein the first wiring layer serves as a jumper between the conductive structure and the second wiring layer.

6. The method of claim 4, wherein a height of the conductive structure is in a range of 1500 to 4000 angstroms.

7. The method of claim 4, wherein a width of the conductive structure at the bottom is in a range of 35 nm to 45 nm.

8. The method of claim 4, wherein a width of the first wiring layer is in a range of 60 nm to 180 nm.

9. The method of claim 1, wherein a thickness of the gate layer is in a range of 700 angstroms to 1200 angstroms.

10. A semiconductor device, comprising:
a substrate; and
a transistor on the substrate,
wherein a gate of the transistor has a thickness in a range of 700 angstroms to 1200 angstroms.

11. The semiconductor device of claim 10, wherein the transistor further comprises:
a conductive contact layer on source and drain regions of the transistor; and
a gate conductive layer on the gate, and wherein the semiconductor device further comprises:
a conductive structure electrically connected to the conductive contact layer; and
a first wiring layer electrically connected to the conductive structure.

12. The semiconductor device of claim 11, further comprising:
a second wiring layer electrically connected to the first wiring layer, wherein the first wiring layer serves as a jumper between the conductive structure and the second wiring layer.

13. The semiconductor device of claim 11, wherein a height of the conductive structure is in a range of 1500 angstroms to 4000 angstroms.

14. The semiconductor device of claim 11, wherein a width of the conductive structure at the bottom is in a range of 35 to 45 nm.

15. The semiconductor device of claim 11, wherein a width of the first wiring layer is in a range of 60 nm to 180 nm.

16. A semiconductor device, comprising:
a transistor;
a conductive structure electrically connected to the transistor; and
a first wiring layer and a second wiring layer, wherein the first wiring layer serves as a jumper between the conductive structure and the second wiring layer.

17. The semiconductor device of claim 16, wherein the transistor comprises a high-voltage transistor, and the gate of the high-voltage transistor has a thickness in a range of 700 to 1200 angstroms.

18. The semiconductor device of claim 16, wherein a height of the conductive structure is in a range of 1500 to 4000 angstroms.

19. The semiconductor device of claim 16, wherein a width of the conductive structure at the bottom is in a range of 35 to 45 nm.

20. The semiconductor device of claim 16, wherein a width of the first wiring layer is in a range of 60 to 180 nm.
